(19) United States
(12) Patent Application Publication
(10) Pub. No.: US 2024/0372500 A1
(43) Pub. Date: Nov. 7, 2024

(54) METHOD AND SYSTEM FOR CORRECTING A MEASURED WINDING TEMPERATURE OF AN ELECTRICAL MACHINE, IN PARTICULAR FOR AN ELECTRIC-PROPULSION OR HYBRID-PROPULSION VEHICLE

(71) Applicant: AMPERE S.A.S, Boulogne Billancourt (FR)

(72) Inventor: Bassel ASSAAD, Guyancourt Cedex (FR)

(73) Assignee: AMPERE S.A.S, Boulogne Billancourt (FR)

(21) Appl. No.: 18/576,019

(22) PCT Filed: Jun. 30, 2022
(86) PCT No.: PCT/EP2022/068139

§ 371 Date: Jul. 3, 2024

(30) Foreign Application Priority Data
Jul. 2, 2021 (FR) 2107212

(51) Int. Cl. H02P 29/64; G01K 1/14; H02P 27/06

(52) U.S. Cl. CPC H02P 29/64; G01K 1/14; H02P 27/06

(57) ABSTRACT

A method for correcting a temperature measurement of a winding of an AC electrical machine of an electric-propulsion or hybrid-propulsion motor vehicle, which comprises constantly retrieving a measured temperature value of the winding measured by a temperature sensor located on the surface of the winding, a measured value of the speed of rotation of the electrical machine measured by a position sensor, and a measured value of the effective current flowing through an inverter controlling the electrical machine measured by a current sensor. The method corrects the measured winding temperature value based on the measured temperature and an estimate of the corrected total heat loss of the electrical machine, the estimate of the corrected total heat loss depending on an estimate of the Joule-effect losses corrected based on a correction of the heat losses due to the alternating nature of the electrical machine and a correction of the heat losses due to the torque and the speed of rotation of the electrical machine.

The present invention relates to the field of rotating electric machines, and in particular measuring the temperature of such machines.

In the case of electric machines notably comprising a winding, the temperature probes, such as, for example, negative temperature sensors, called “CTN”, are disposed on the outer surfaces of the coil heads, because of the constraints of the procedure for manufacturing such electric machines.

The measured temperature values move away from the real temperature values at the centre of the winding, in particular on dynamic driving profiles. This disparity is reinforced by the presence of contact resistances between the winding wires and the temperature probe that is away from the core of the winding, as well as by the delay between the measurement and the conduction of heat along the copper wires.

In the context of a cooling of an electric machine by injection of oil on the coil heads, the phenomenon of underestimation of the maximum temperatures of the winding increases.

Generally, over a plurality of electric machine topologies, the centre of the winding constitutes the hottest point, such that it is essential to monitor it continuously on motor vehicles with electric or hybrid propulsion.

And underestimation of the temperature of the winding can lead to an incorrect evaluation of the state of health and the thermal state of the winding and an overheating above the thermal grade of the winding which can provoke the destruction, in particular, of the insulations of the copper wires of the winding, as well as a short circuit, and consequently, a removal from service of the electric machine or a hazard to the driver.

It is known practice to apply margins to the temperature measurements in order to limit the above problems. However, such an application of margins can greatly limit the performance levels of the electric machine, which is felt directly by the driver by a limitation of the torque demanded.

Moreover, in a three-phase AC electric machine, when the vehicle is kept immobile on a slope by pressing on the accelerator pedal, the rotor does not revolve. Thus, the electric current is no longer alternating between the three phases. All of the current thus generally passes into just one of the three phases, which is therefore the only one to be heated, or, in other cases, into two of the three phases, which are therefore the only ones to be heated. Now, generally, the temperature probe is positioned on the face of one of the three phases in a three-phase machine. In the case where the temperature probe is not on the face of the phase supplied with current, the phase on the face of which it is positioned remains cold, and the probe does not therefore detect the heating of the machine, which can reach a limit temperature.

The aim of the invention is therefore to improve the temperature measurements of a winding of an electric machine, while guaranteeing the performance levels of the electric machine and the protection of the electric machine against overheating.

The subject of the present invention is a method for correcting a temperature measurement of a winding of an AC electric machine, notably of a motor vehicle with electric or hybrid propulsion, wherein there is retrieved, at each instant, a measured temperature value of the winding measured by a temperature probe situated on the surface of the winding, a measured rotation speed value of said electric machine measured by a position sensor and a measured value of the RMS current passing through an inverter controlling the electric machine and measured by a current sensor.

The measured temperature value of the winding is corrected as a function of the measured temperature and of an estimation of the corrected total heat losses of the electric machine, the estimation of the corrected total heat losses depending on an estimation of the losses by Joule effect corrected as a function of a correction of the heat losses due to the alternating nature of the electric machine and of a correction of the heat losses due to the torque and to the rotation speed of the electric machine.

The estimation of the corrected total heat losses of the electric machine makes it possible to refine a correction of the measured temperature of the winding based solely on an estimation of the heat losses by Joule effect. Indeed, other sources can be the origin of heat losses, like known physical phenomena deriving from the alternating nature of the electric machine, such as the skin effect, or the eddy currents, or even like additional losses in the machine, primarily rotor losses and mechanical losses, dependent therefore on the rotation speed of the electric machine and on its torque, particularly in the case of a machine cooled by oil injection.

The estimation of the corrected total heat losses of the electric machine therefore allows for a more accurate correction of the measured temperature of the winding.

Moreover, the correction of the measured temperature of the winding as a function on the one hand of the estimation of the total heat losses of the electric machine, and on the other hand as a function of the measured temperature of the winding itself makes it possible to manage the amplitude of the correction applied as a function of the limit temperature of the machine. Indeed, at low temperature for example, a risk of exceeding this limit temperature is low, and therefore the application of a significant correction has, above all, the effect of limiting the performance levels of the electric machine. The inclusion of the measured temperature therefore allows for a better management of the electric machine, in order to better guarantee its performance levels without the risk of overheating.

The correction of the heat losses due to the alternating nature of the machine makes it possible to correct the heat losses due to physical phenomena deriving from the alternating nature of the electric machine such as, for example, the skin effect, and the eddy currents. These effects appear above all at high rotation speeds of the machine, and the correction thereof makes it possible to have an estimation of the total heat losses of the electric machine that is more accurate at high speeds. Thus, the correction to be made to the measured temperature of the winding is refined.

The correction of the heat losses due to the torque and to the rotation speed of the electric machine makes it possible to manage any overheating in the case of the vehicle being kept immobile on a slope by pressing on the accelerator pedal. Indeed, in this situation, the speed of the machine is zero despite a continuous torque. This means that the current powers the machine and heats it. A correction of the heat losses founded on the torque and the speed of the machine makes it possible to take this situation into account, and to avoid the overheating, even in the case where the temperature probe is not placed in such a way as to detect the heating of the machine. However, the benefit of this correction is not limited to this situation, and the effect of increased accuracy on the correction of the measured temperature is present throughout the torque-rotation speed space of the electric machine.

Advantageously, the correction of the losses due to the alternating nature of the electric machine comprises the application of a first correction factor derived from prior tests performed on an electric machine on a test bench.

For example, thermocouples are installed at the core of the winding of the prototypes, which is not possible in an electric machine installed in a motor vehicle.

The first correction factor is determined as a function of the measured temperature value and of the measured rotation speed value of said electric machine.

Advantageously, the correction of the losses due to the torque and to the rotation speed of the electric machine comprises the application of a second correction factor derived from prior tests performed on an electric machine on a test bench, and determined as a function of the measured rotation speed value of said electric machine and on an estimation of its torque.

Advantageously, the estimation of the losses by Joule effect is calculated as a function of the RMS current and of the measured temperature value of the winding.

The dependence of these losses on the temperature, by the changing of the electrical resistance as a function of temperature, is therefore taken into account.

Advantageously, a temperature correction factor derived from prior tests performed on an electric machine on a test bench is determined as a function of the measured temperature of the winding and of the estimation of the corrected total heat losses, the estimation of the corrected total heat losses being the product of the estimation of the losses by Joule effect, of the correction of the heat losses due to the alternating nature of the electric machine and of the correction of the heat losses due to the torque and to the rotation speed of the electric machine.

Advantageously, an intermediate correction value is calculated by adding said correction factor with the measured temperature value of the winding.

It is then possible to calculate a final corrected value by filtering by a discrete state integrator of the intermediate corrected value multiplied by a coefficient.

According to a second aspect, the invention relates to a system for correcting the temperature measurement of the winding of an electric machine, notably of a motor vehicle with electric or hybrid propulsion, comprising a temperature probe situated on the surface of the winding, a position sensor measuring the rotation speed of the electric machine and a current sensor measuring the RMS current passing through an inverter controlling the electric machine.

The system comprises a module configured to determine a temperature correction function as a function of the measured temperature of the winding measured by the temperature probe and as a function of an estimation of the corrected total heat losses of the electric machine performed in a module for estimating the corrected total heat losses of the electric machine.

Advantageously, the module for estimating the total heat losses of the electric machine is configured to determine the estimation of the corrected total heat losses of the electric machine as a function of the RMS current, of the measured temperature value, of the measured rotation speed of the electric machine, and of an estimation of the torque delivered by the electric machine, and in which the module for estimating the total heat losses of the electric machine comprises a module for estimating losses by Joule effect, a module for correcting the losses due to the alternating nature of the electric machine, and a module for correcting the losses due to the torque and to the rotation speed of the electric machine.

Preferably, the module for correcting the losses due to the alternating nature of the electric machine is configured to determine a first correction factor for the losses due to the alternating nature of the electric machine as a function of the measured temperature value and of the measured rotation speed value of said electric machine.

Advantageously, the module for correcting the losses due to the torque and to the rotation speed of the electric machine is configured to determine a second correction factor for the losses due to the torque and to the rotation speed of the electric machine as a function of the measured rotation speed value of said electric machine and of an estimation of the torque.

Advantageously, the module for estimating the losses due to Joule effect is configured to calculate an estimation of the losses by Joule effect as a function of the RMS current and of the measured temperature value of the winding.

Advantageously, the module for estimating the total heat losses of the electric machine comprises a first multiplier configured to multiply the correction factors of the losses due to the alternating nature of the electric machine and of the losses due to the torque and to the rotation speed of the electric machine and delivering a global correction factor for the heat losses, and a second multiplier configured to multiply the estimation of the losses by Joule effect and the global correction factor of the heat losses, and delivering an estimation of the total heat losses of the electric machine.

Preferably, the correction module comprises a first summer configured to add the temperature correction factor with the measured temperature value of the winding and delivering an intermediate corrected value.

Advantageously, the correction module comprises a module for applying a coefficient to the intermediate corrected value and a filtering module comprising a discrete state integrator and delivering a final corrected value.

The invention also relates to a motor vehicle with electric or hybrid propulsion comprising at least one electric machine, an inverter, a means for controlling the inverter, a system for managing the performance levels of the electric machine, and a system for correcting the temperature measurement of the winding according to the invention intended to be incorporated in the inverter control means and configured to deliver to the system for managing the performance levels of the electric machine a corrected temperature value of the winding.

Other aims, features and advantages of the invention will become apparent on reading the following description, given purely as a nonlimiting example, and with reference to the attached drawings in which:

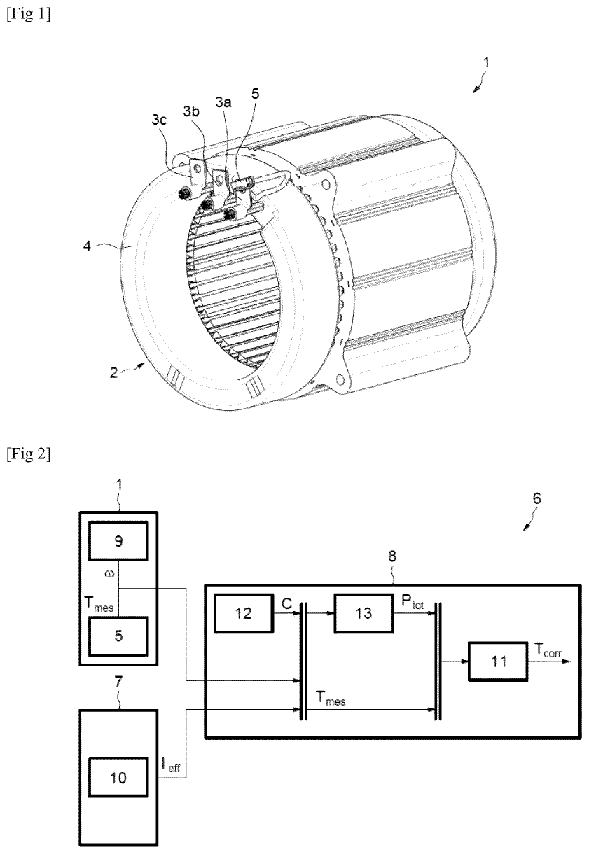

FIG. 1 illustrates a three-phase electric machine:

FIG. 2 illustrates, schematically, a motor vehicle with electric or hybrid propulsion comprising a winding temperature correction system according to the invention:

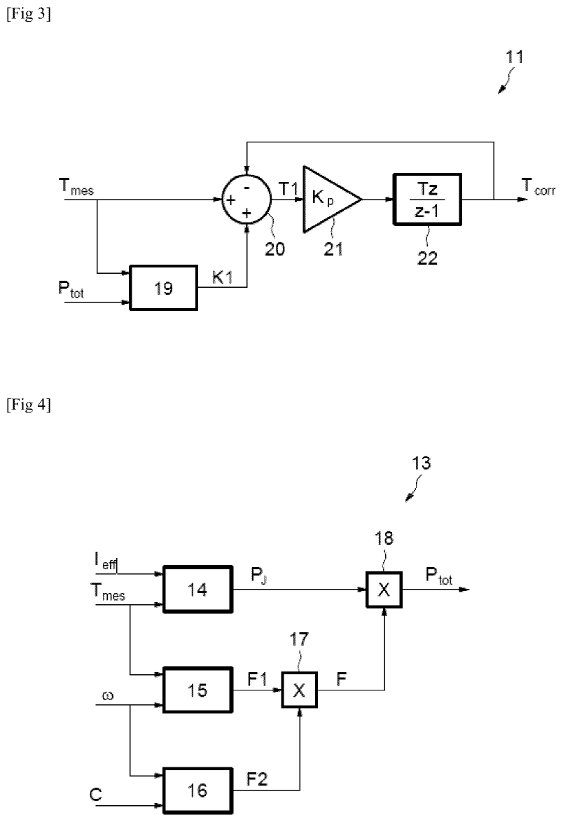

FIG. 3 represents in detail the winding temperature correction system of FIG. 2:

FIG. 4 represents the module for estimating the corrected total heat losses at the input of the winding temperature correction system of FIG. 3; and

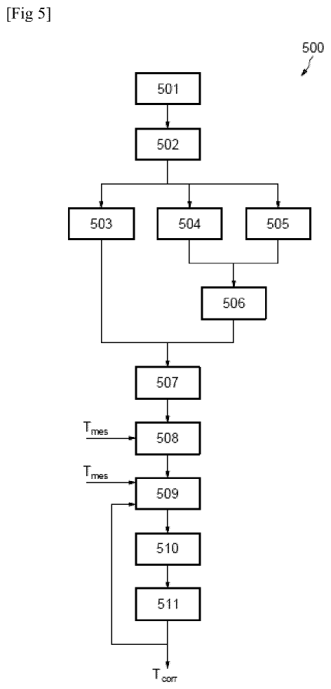

FIG. 5 represents a mode of implementation of a winding temperature correction method according to the invention.

FIG. 1 illustrates a three-phase electric machine 1 comprising a winding 2 and three current supply phases 3a, 3b and 3c disposed on the heads of coils 4 of the winding 2. A temperature probe 5 is disposed on the heads of coils 4 of the winding 2, borne by the phase 3a of the electric machine 1 and measures, at each instant, the temperature Tmes of the winding 2.

As illustrated in FIG. 2, the motor vehicle 6 with electric or hybrid propulsion comprises at least one electric machine 1, an inverter 7 and an inverter control means, comprising a software control means 8 intended to control the inverter 7 of the electric machine 1.

In addition to the temperature probe 5, a position sensor 9 is mounted in the electric machine 1 and makes it possible to measure a rotation speed value ω of said electric machine 1.

A current sensor 10 is mounted in the inverter 7 and makes it possible to measure the RMS current Ieff passing through the inverter 7.

The motor vehicle 6 further comprises a system 11 for correcting the temperature of the winding 2 intended to be incorporated in the software 8 that makes it possible to control the electric machine 1. The system 11 delivers a corrected value Tcorr of the temperature of the winding 2. For example, the corrected value Tcorr is delivered to a system for managing the performance levels of the electric machine 1, not represented in the figures, of the inverter control means.

The software 8 of the inverter control means receives as input the measured temperature Tmes derived from the temperature probe 5, the measured rotation speed value, or speed, denoted ω of the electric machine 1 derived from the position sensor 9, the RMS current Ieff derived from the current sensor 10, and an estimation of the engine torque C determined in a module 12 for estimating the engine torque according to the known methods as a function of electromagnetic data on the input currents of the electric machine 1.

The temperature correction system 11 of the winding 2 receives as input the measured temperature Tmes of the winding 2 on the one hand and an estimation Pₜₒₜ of the corrected total heat losses on the other hand. This estimation Pₜₒₜ of the corrected total losses is obtained from a module 13 for estimating the corrected total heat losses illustrated in detail in FIG. 4.

The module 13 for estimating the corrected total heat losses comprises a module 14 for estimating the losses by Joule effect P_{J}, a module 15 for correcting the heat losses due to the alternating nature of the electric machine 1 and a module 16 for correcting the heat losses due to the torque and to the rotation speed of the electric machine 1. The module 13 for estimating the corrected total heat losses receives as input the measured temperature Tmes of the winding 2, the measured value of the rotation speed, or speed, denoted ω, of the electric machine 1, the RMS current Ieff, and the estimation of the engine torque C.

The module 14 for estimating the losses by Joule effect determines an estimation of the losses by Joule effect P_{J} as a function of the RMS current Ieff and of the measured temperature Tmes. The dependence of these losses on temperature, by the changing of the electrical resistance R as a function of temperature, is also taken into account by the following equation:

P_{J}(T)=R(T)·Ieff² Eq.1

The module 15 for correcting the heat losses due to the alternating nature of the machine 1 determines a first correction factor F1 of the heat losses as a function of the measured temperature value Tmes of the winding 2 and of the measured value ω of the rotation speed of the electric machine 1. This first correction factor F1 is derived from prior tests performed on an electric machine on a test bench, and varies as a function of the measured temperature values Tmes of the winding 2 on the one hand, and of the measured values ω of the rotation speed of the electric machine 1 on the other hand.

The module 16 for correcting the heat losses due to the torque and to the rotation speed of the electric machine 1 determines a second correction factor F2 of the heat losses as a function of the measured value w of the rotation speed of the electric machine 1 and of the estimation of the torque C. This second correction factor F2 is derived from prior tests performed on an electric machine on a test bench, and varies as a function of the torque C estimation values and of the measured values ω of the rotation speed of the electric machine. The table of the factors F2 is as a function of the torque and of the rotation speed, or speed, of the electric machine 1.

In the case of holding on a slope, the rotation speed is very low, of the order of 0 to 10 revolutions per minute. In this case, the correction factor F2 delivered by the module 16 is much higher than in the rest of the spectrum of rotation speeds of the machine, so as to avoid an overheating of the electric machine 1 in the case described previously in which the temperature probe is not placed on the right phase 3a. Thus, the correction factor for low rotation speeds can for example be of the order of 15 times the correction factor F2 delivered for rotation speeds that are higher and around 10 revolutions per minute.

The module 13 for estimating the corrected total heat losses further comprises a first multiplier 17 configured to multiply the first and second correction factors F1 and F2, and delivering a global correction factor F of the heat losses, and a second multiplier 18 configured to multiply the global correction factor F of the heat losses with the estimation of the losses by Joule effect P_{J}, thus delivering an estimation Pₜₒₜ of the total heat losses of the electric machine 1.

As described previously, the system 11 for correcting the temperature of the winding 2 receives as input the measured temperature Tmes on the one hand and an estimation Pₜₒₜ of the corrected total heat losses on the other hand.

The temperature correction system 11 of the winding 2, illustrated in detail in FIG. 3, comprises a module 19 for correcting the measured temperature Tmes measured by the temperature probe 5 delivering a correction factor K1 as a function of the estimation Pₜₒₜ of the total heat losses of the machine 1 and as a function of the measured temperature Tmes of the winding 2. The correction factor K1 of the temperature is derived from prior tests performed on an electric machine on a test bench, and varies as a function of the measured temperature values Tmes of the winding 2 on the one hand, and of the estimation Pₜₒₜ of the total heat losses of the machine on the other hand.

The correction module 19 thus delivers a correction factor K1 for the measured temperature Tmes that is different for a same measured temperature value but for two different estimated total loss values.

Similarly, the correction module 19 delivers a correction factor K1 for the measured temperature Tmes that is different for a same estimated total loss value but for two different measured temperatures.

This way, the correction is much more accurate, and it is possible to decide not to over-correct a measured temperature, if the latter is not very high despite strong estimated losses, the probability of the limit temperature being exceeded remaining low.

The temperature correction system 11 of the winding 2 further comprises a summer 20 configured to add the measured temperature value Tmes with the correction factor K1 of the measured temperature Tmes, and delivering an intermediate correction value T1.

The temperature correction system 11 of the winding 2 also comprises a module 21 for applying a coefficient Kp at the input of a filtering module 22 comprising a discrete state integrator and delivering a final corrected value Tcorr. The final corrected value Tcorr is then looped back and subtracted in the summer 20. The coefficient Kp is the gain of the filter applied in the module 22.

Thus, the temperature correction system 11 makes it possible to effectively realign the measured temperature Tmes measured on the surface of the winding on the real temperature at the core of the winding.

The flow diagram represented in FIG. 5 illustrates an example of method 500 implemented by the system represented in FIG. 2.

In a first step 501, the measured temperature value Tmes of the winding 2, measured by the temperature probe 5, the rotation speed value w of said electric machine 1 measured by the position sensor 9 and the measurement of the RMS current Ieff passing through the inverter 7 measured by the current sensor 10, are retrieved.

In the step 502, the engine torque C delivered by the electric machine 1 is estimated.

In the step 503, an estimation of the losses by Joule effect P_{J} is calculated, as a function of the RMS current Ieff and of the measured temperature Tmes.

The dependence of these losses P_{J} on temperature, by the changing of the electrical resistance R as a function of temperature, is also taken into account by the following equation:

$${P}_{J} ( T ) = R ( T ) \cdot {Ieff}^{2} \qquad Eq . 1$$

In the next step 504, a first correction factor F1 for the heat losses due to the alternating nature of the electric machine 1 is determined.

The first correction factor F1 varies as a function of the measured value of the temperature Tmes of the winding 2 and of the rotation speed of the electric machine. The first correction factor F1 is derived from prior tests performed on an electric machine on a test bench.

In the step 505, a second correction factor F2 for the heat losses due to the torque and to the rotation speed of the electric machine 1 is determined.

The second correction factor F2 varies as a function of the value of the rotation speed of the electric machine 1 and of the estimation of the torque C. The second correction factor F2 is derived from prior tests performed on an electric machine on a test bench.

In the step 506, a global correction factor F of the heat losses is calculated by multiplying said first and second correction factors F1, F2 and, in the step 507, the estimation of the corrected total heat losses of the electric machine 1 is calculated by multiplying the global correction factor F with the value of estimation of the losses by Joule effect P_{J} calculated in the step 503.

In the step 508, a correction factor K1 is determined for the measured temperature Tmes measured by the temperature probe 5.

The correction factor K1 varies as a function of the estimation of the total heat losses of the machine 1 and as a function of the measured temperature Tmes of the winding 2. The correction factor K1 of the temperature is derived from prior tests performed on an electric machine on a test bench.

In the step 509, an intermediate corrected value T1 is determined by adding said correction factor K1 of the measured temperature Tmes with the measured temperature value Tmes of the winding 2.

The steps 510 and 511 implement a regulation loop on this intermediate corrected value T1. In the step 510, a coefficient Kp is applied to the error on said intermediate corrected value T1 and, in the step 511, a final corrected value Tcorr is calculated by filtering by a discrete state integrator of the preceding value which is the error multiplied by the gain Kp. The transfer function in z of this discreet integrator is of the form:

$$\frac{{T}_{z}}{z - 1}$$

With T the sampling period.

The final corrected value Tcorr is then looped back and subtracted in the step 509, from the intermediate corrected value T1.

The method for correcting the measured temperature with respect to the real temperature at the core of the winding is constructed and powered as a function of experimental measurements performed beforehand on prototypes. For example, thermocouples are installed at the core of the winding of the prototypes, which is not possible in an electric machine installed in a motor vehicle.

By virtue of the invention, the temperature measurement of a winding of an electric machine is improved, approximating the real temperature value at the core of the winding, while guaranteeing the performance levels of the electric machine and the protection of the electric machine against overheating.

1. A method for correcting a temperature measurement of a winding of an alternating current electric machine, of a motor vehicle with electric or hybrid propulsion, the method comprising:
retrieving, at each instant, a measured temperature value of the winding measured by a temperature probe situated on the surface of the winding, a measured rotation speed value of said electric machine measured by a position sensor and a measured value of the RMS current passing through an inverter controlling the electric machine and measured by a current sensor, and
correcting the measured winding temperature value as a function of the measured temperature and of an estimation of corrected total heat losses of the electric machine, the estimation of the corrected total heat losses depending on an estimation of the losses by Joule effect corrected as a function of a correction of the heat losses due to the alternating nature of the electric machine and of a correction of the heat losses due to the torque and to the rotation speed of the electric machine.

2. The correction method as claimed in claim 1, wherein the correction of the losses due to the alternating nature of the electric machine comprises applying a first correction factor derived from prior tests performed on an electric machine on a test bench, and determined as a function of the measured temperature value and of the measured rotation speed value of said electric machine.

3. The correction method as claimed in claim 1, wherein the correction of the losses due to the torque and to the rotation speed of the electric machine comprises applying a second correction factor derived from prior tests performed on an electric machine on a test bench, and determined as a function of the measured rotation speed value of said electric machine and of an estimation of the torque.

4. The correction method as claimed in claim 1, wherein the estimation of the losses by Joule effect is calculated as a function of the RMS current and of the measured temperature value of the winding.

5. The correction method as claimed in claim 1, further comprising determining a correction factor of the temperature derived from prior tests performed on an electric machine on a test bench as a function of the measured temperature of the winding and of the estimation of the corrected total heat losses, the estimation of the corrected total heat losses being the product of the estimation of the losses by Joule effect, of the correction of the heat losses due to the alternating nature of the electric machine and of the correction of the heat losses due to the torque and to the rotation speed of the electric machine.

6. The correction method as claimed in claim 5, further comprising calculating an intermediate correction value by adding said correction factor with the measured temperature value of the winding.

7. The method for correcting the temperature measurement of the winding as claimed in claim 6, further comprising calculating a final corrected value by filtering by a discrete state integrator of the intermediate correction value multiplied by a coefficient.

8. A system for correcting the temperature measurement of the winding of an electric machine, of a motor vehicle with electric or hybrid propulsion, comprising:
a temperature probe situated on the surface of the winding,
a position sensor measuring the rotation speed of the electric machine,
a current sensor measuring the RMS current passing through an inverter controlling the electric machine, and
a module configured to determine a temperature correction factor as a function of the measured temperature of the winding measured by the temperature probe and as a function of an estimation of the corrected total heat losses of the electric machine performed in a module for estimating the corrected total heat losses of the electric machine.

9. The correction system as claimed in claim 8, wherein the module for estimating the total heat losses of the electric machine is configured to determine the estimation of the corrected total heat losses of the electric machine as a function of the RMS current, of the measured temperature value, of the measured rotation speed of the electric machine, and of an estimation of the torque delivered by the electric machine, and wherein the module for estimating the total heat losses of the electric machine comprises a module for extimating the losses by Joule effect, a module for correcting the losses due to the alternating nature of the electric machine, and a module for correcting the losses due to the torque and to the rotation speed of the electric machine.

10. The correction system as claimed in claim 9, wherein the module for correcting the losses due to the alternating nature of the electric machine is configured to determine a first correction factor for the losses due to the alternating nature of the electric machine as a function of the measured temperature value and of the measured rotation speed value of said electric machine.

11. The correction system as claimed in claim 9, wherein the module for correcting the losses due to the torque and to the rotation speed of the electric machine is configured to determine a second correction factor for the losses due to the torque and to the rotation speed of the electric machine as a function of the measured rotation speed value of said electric machine and of an estimation of the torque.

12. The correction system as claimed in claim 9, wherein the module for estimating the losses due to Joule effect is configured to calculate an estimation of the losses by Joule effect as a function of the RMS current and of the measured temperature value of the winding.

13. The correction system as claimed in claim 9, wherein the module for estimating the total heat losses of the electric machine comprises a first multiplier configured to multiply the correction factors of the losses due to the alternating nature of the electric machine and of the losses due to the torque and to the rotation speed of the electric machine and delivering a global correction factor of the heat losses, and a second multiplier configured to multiply the estimation of the losses by Joule effect and the global correction factor of the heat losses, and delivering an estimation of the total heat losses of the electric machine.

14. The correction system as claimed in claim 8, comprising a first summer configured to add the temperature correction factor with the measured temperature value of the winding and delivering an intermediate corrected value.

15. The correction system as claimed in claim 14, further comprising a module for applying a coefficient to the intermediate corrected value and a filtering module comprising a discrete state integrator and delivering a final corrected value.

16. A motor vehicle with electric or hybrid propulsion comprising at least one electric machine, an inverter, a means for controlling the inverter, a system for managing the performance levels of the electric machine, and a system for correcting the temperature measurement of the winding as claimed in claim 8 incorporated in the inverter control means and configured to deliver to the system for managing the performance levels of the electric machine, a corrected temperature value of the winding.
